(19) United States
(12) Patent Application Publication
(10) Pub. No.: US 2026/0283020 A1
(43) Pub. Date: Sep. 17, 2026

(54) SEMICONDUCTOR APPARATUS AND METHOD FOR MANUFACTURING THE SAME

(71) Applicant: Kioxia Corporation, Tokyo (JP)

(72) Inventors: Tomoya SANUKI, Yokohama Kanagawa (JP); Masatoshi KAWATO, Kameyama Mie (JP); Shinya WATANABE, Yokkaichi Mie (JP); Mie MATSUO, Kamakura Kanagawa (JP); Takuma AOYAMA, Fujisawa Kanagawa (JP)

(73) Assignee: Kioxia Corporation, Tokyo (JP)

(21) Appl. No.: 19/324,436

(22) Filed: Sep. 10, 2025

(30) Foreign Application Priority Data
Mar. 13, 2025 (JP) 2025-040626

(51) Int. Cl. H01L 25/16; H01L 23/00

(52) U.S. Cl. CPC H10W 90/00; H10W 72/0198; H10W 80/312; H10W 90/792

(57) ABSTRACT

A semiconductor apparatus includes a logic chip on which a logic circuit is disposed; and a plurality of memory chips stacked on the logic chip that is face up, wherein each of the plurality of memory chips has a channel formed of an oxide semiconductor layer.

### CROSS REFERENCE TO RELATED APPLICATIONS

This application is based upon and claims the benefit of priority from the prior Japanese Patent Application No. 2025-040626, filed on Mar. 13, 2025, the entire contents of which are incorporated herein by reference.

### FIELD

An embodiment of the present invention relates to a semiconductor apparatus and a method for manufacturing the same.

### BACKGROUND

A high bandwidth memory (HBM), which has a transmission speed higher than that of a conventional dynamic random access memory (DRAM), has attracted attention. In the HBM, it has been proposed to adopt hybrid bonding (HB) for bonding stacked memory chips.

In HB, heat treatment at a high temperature of 300 to 400° C. is required at the time of bonding, and the temperature exceeds the temperature limit of the existing memory chip, so that a failure may occur.

### BRIEF DESCRIPTION OF THE DRAWINGS

FIG. 1 is a diagram illustrating a structure of a semiconductor apparatus according to an embodiment;

FIG. 2A is a cross-sectional view illustrating a bonding mode between memory chips according to the present embodiment;

FIG. 2B is a cross-sectional view illustrating a bonding mode between memory chips in a comparative example;

FIG. 3 is a graph illustrating the relationship between a heat treatment temperature in HB and the expansion coefficient of copper, which is the material of a pad;

FIG. 4 is a graph illustrating characteristics of a memory chip in which a VRT failure occurs;

FIG. 5A is a cross-sectional view of a memory chip having a channel formed of an oxide semiconductor layer;

FIG. 5B is a perspective view illustrating an example of a memory chip having a three-dimensional structure;

FIG. 6A is a cross-sectional view illustrating a bonding mode between a logic chip and a memory chip at the lowermost stage in the semiconductor apparatus according to the present embodiment;

FIG. 6B is a cross-sectional view illustrating a bonding mode between a logic chip and a memory chip at the lowermost stage in a semiconductor apparatus according to the comparative example;

FIG. 7 is a table comparing the heat treatment temperature and the orientation of the logic chip in the present embodiment and the comparative example;

FIG. 8A is a process diagram of a first process flow;

FIG. 8B is a process diagram following FIG. 8A;

FIG. 8C is a process diagram following FIG. 8B;

FIG. 8D is a process diagram following FIG. 8C;

FIG. 8E is a process diagram following FIG. 8D;

FIG. 8F is a process diagram following FIG. 8E;

FIG. 8G is a process diagram following FIG. 8F;

FIG. 8H is a process diagram following FIG. 8G;

FIG. 8I is a process diagram following FIG. 8H;

FIG. 8J is a process diagram following FIG. 8I;

FIG. 8K is a process diagram following FIG. 8J;

FIG. 8L is a process diagram following FIG. 8K;

FIG. 8M is a process diagram following FIG. 8L;

FIG. 8N is a process diagram following FIG. 8M;

FIG. 8O is a process diagram following FIG. 8N;

FIG. 8P is a process diagram following FIG. 8O;

FIG. 8Q is a process diagram following FIG. 8P;

FIG. 9A is a process diagram of a second process flow;

FIG. 9B is a process diagram following FIG. 9A;

FIG. 9C is a process diagram following FIG. 9B;

FIG. 9D is a process diagram following FIG. 9C;

FIG. 9E is a process diagram following FIG. 9D;

FIG. 9F is a process diagram following FIG. 9E;

FIG. 9G is a process diagram following FIG. 9F;

FIG. 9H is a process diagram following FIG. 9G;

FIG. 9I is a process diagram following FIG. 9H;

FIG. 9J is a process diagram following FIG. 9I;

FIG. 10A is a process diagram illustrating a method for manufacturing the semiconductor apparatus according to the comparative example;

FIG. 10B is a process diagram following FIG. 10A;

FIG. 10C is a process diagram following FIG. 10B;

FIG. 10D is a process diagram following FIG. 10C;

FIG. 10E is a process diagram following FIG. 10D;

FIG. 10F is a process diagram following FIG. 10E;

FIG. 10G is a process diagram following FIG. 10F;

FIG. 10H is a process diagram following FIG. 10G;

FIG. 10I is a process diagram following FIG. 10H;

FIG. 10J is a process diagram following FIG. 10I;

FIG. 10K is a process diagram following FIG. 10J;

FIG. 10L is a process diagram following FIG. 10K;

FIG. 11A is a cross-sectional view of the semiconductor apparatus according to the present embodiment;

FIG. 11B is a cross-sectional view of the logic chip; and

FIG. 11C is a cross-sectional view of a logic chip having a configuration different from that in FIG. 11B.

### DETAILED DESCRIPTION

A semiconductor apparatus according to an embodiment includes: a logic chip on which a logic circuit is disposed; and
a plurality of memory chips stacked on the logic chip that is face up, in which
each of the plurality of memory chips has a channel formed of an oxide semiconductor layer.

Hereinafter, an embodiment of a semiconductor apparatus and a method for manufacturing the same will be described with reference to the drawings. Main components of the semiconductor apparatus will be mainly described below, but the semiconductor apparatus may have components and functions that are not illustrated or described. The following description does not exclude the components and functions that are not illustrated or described.

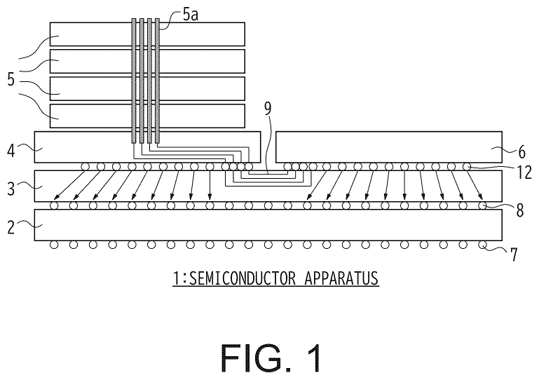

FIG. 1 is a diagram illustrating a structure of a semiconductor apparatus 1 according to an embodiment. The semiconductor apparatus 1 according to the embodiment is a HBM, and is characterized in that data can be written and read at a high transmission speed. The semiconductor apparatus 1 according to the embodiment illustrated in FIG. 1 includes a substrate 2, an interposer 3, a logic chip 4, a plurality of stacked memory chips 5, and a silicon on chip (SoC) 6. Note that a configuration in which the interposer 3 is omitted can also be adopted.

The substrate 2 is a support substrate of a package member (not illustrated in FIG. 1). On a lower surface of the substrate 2, a plurality of connection members (for example, solder balls) 7 for connecting to a main substrate or the like (not illustrated) is disposed.

The interposer 3 is disposed on the substrate 2. A plurality of pads are disposed on each of an upper surface and a lower surface of the interposer 3. Each of the pads on the lower surface of the interposer 3 is connected to a corresponding pad on the upper surface of the substrate 2 by a bump 8.

The logic chip 4 and the SoC 6 are disposed on the upper surface of the interposer 3. In the interposer 3, a plurality of wirings 9 for transmitting a plurality of signals to be transmitted and received between the logic chip 4 and the SoC 6 are disposed, and a plurality of through silicon vias (TSVs) for connecting each of the pads on the upper surface and the corresponding pad on the lower surface are provided. The connection between the interposer 3 and the logic chip 4 and the connection between the interposer 3 and the SoC 6 are performed, for example, by connecting the pads with bumps 12.

The SoC 6 is, for example, a graphics processing unit (GPU) or a central processing unit (CPU).

The plurality of memory chips 5 are stacked on the logic chip 4. The memory chips 5 are bonded to each other by hybrid bonding (HB). As a result, the transmission speed can be increased as compared with a case where the memory chips are bonded via the pad and the bump.

Each of the memory chips 5 performs signal transmission at high speed by bonding pads connected to a TSV 5a by HB. Each of the memory chips 5 has a channel formed of an oxide semiconductor layer as described later. As a result, it is possible to increase a heat treatment temperature at the time of bonding the memory chips 5 to each other as compared with a case where a channel formed of a silicon layer is provided. In order to bond the memory chips 5 to each other by HB, it is necessary to perform heat treatment at a high temperature. Since a memory chip 5 having the channel formed of the silicon layer cannot be subjected to heat treatment at a high temperature, HB cannot be adopted.

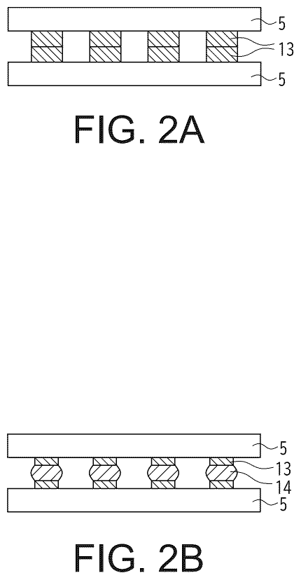

FIG. 2A is a cross-sectional view illustrating a bonding mode between the memory chips 5 in the present embodiment, and FIG. 2B is a cross-sectional view illustrating a bonding mode between memory chips 5 in a comparative example.

In the present embodiment, as illustrated in FIG. 2A, pads 13 of the memory chips 5 are, for example, copper (Cu), and the pads 13 are directly bonded to each other and subjected to heat treatment at a high temperature of 300 to 400° C., so that the memory chips 5 are bonded to each other without deteriorating the reliability of the memory chips 5.

In the comparative example, as illustrated in FIG. 2B, bumps 14 are disposed between pads 13 of the memory chips 5, and the memory chips 5 are bonded to each other by performing heat treatment at a temperature (for example, 200 to 250° C.) at which a failure of the memory chip 5 does not occur.

In the present embodiment, since HB is adopted for bonding the memory chips 5 to each other, the heat treatment temperature needs to be higher than that in the comparative example, but since a bump is unnecessary, a manufacturing process can be simplified, and the transmission speed can be increased.

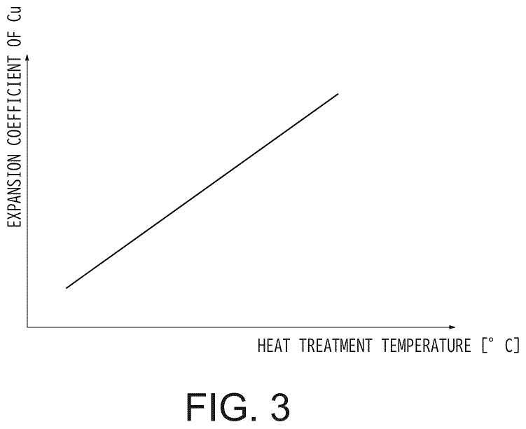

FIG. 3 is a graph illustrating the relationship between the heat treatment temperature in HB and the expansion coefficient of copper (Cu), which is the material of the pad 13. In FIG. 3, the horizontal axis represents the heat treatment temperature [° C.], and the vertical axis represents the expansion coefficient of copper (Cu). As illustrated in FIG. 3, the expansion coefficient of copper (Cu) increases substantially linearly as the heat treatment temperature increases. When the heat treatment temperature is 300 to 400° C., an expansion coefficient sufficient for stably bonding the copper (Cu) of the pads 13 is obtained.

When heat treatment is performed at a temperature of 260° C. or higher in order to bond the memory chips 5 each having the channel formed of the silicon layer, there is a possibility that a variable retention time (VRT) failure occurs in the memory chip 5.

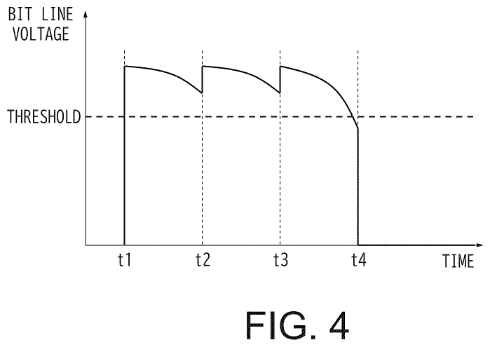

FIG. 4 is a graph illustrating characteristics of the memory chip 5 in which the VRT failure occurs due to the heat treatment at a temperature of 260° C. or higher. In FIG. 4, the horizontal axis represents time, and the vertical axis represents a bit line voltage. When data “1” is written to the memory chip 5 at time t1, the bit line voltage at the time of reading is higher than a threshold voltage for determining data “0” and “1” indicated by the broken line. Thereafter, a charge held in each memory cell in the memory chip 5 leaks with time, and the bit line voltage gradually decreases accordingly. In the memory chip 5 including a DRAM, periodic refresh is performed. In the refresh, a process of reading the bit line voltage corresponding to the charge held in each memory cell and writing the charge corresponding to the read bit line voltage to each memory cell again is performed. Time t2 and time t3 in FIG. 4 indicate the timing of refresh. Every time the refresh is performed, the bit line voltage increases.

However, after the refresh at the time t3, the bit line voltage rapidly decreases and becomes lower than the threshold voltage for determining 0 and 1. At time t4 of the next refresh, the bit line voltage is lower than the threshold voltage, and a refresh circuit misunderstands that the memory chip 5 stores the data “0”, and writes the charge corresponding to the data “0” to the memory chip 5. As a result, after the time t4, the stored data of the memory chip 5 is inverted and becomes fail (defective).

As illustrated in FIG. 4, in the memory chip 5 having the channel formed of the silicon layer, heat treatment at a high temperature exceeding 260° C. cannot be performed. The VRT failure occurs when electrons in the channel leak through a PN junction because the PN junction formed in the channel is reverse bias. When the oxide semiconductor layer is used as a channel, a reverse biased PN junction is not formed in the channel, and therefore, there is no possibility that the electrons in the channel leak, and the VRT failure does not occur in principle.

Therefore, in the present embodiment, the memory chip 5 having the channel formed of the oxide semiconductor layer is adopted. The memory chip 5 having the channel formed of the oxide semiconductor layer does not cause the VRT failure even when heat treatment is performed at a high temperature exceeding 260° C. Therefore, for the memory chip 5 having the channel formed of the oxide semiconductor layer, HB, which requires heat treatment at a high temperature, can be adopted for bonding the memory chips 5 to each other.

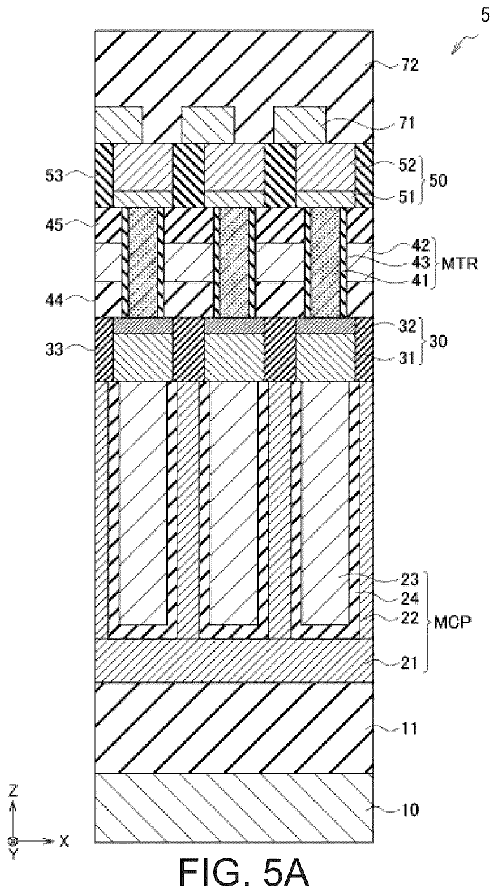

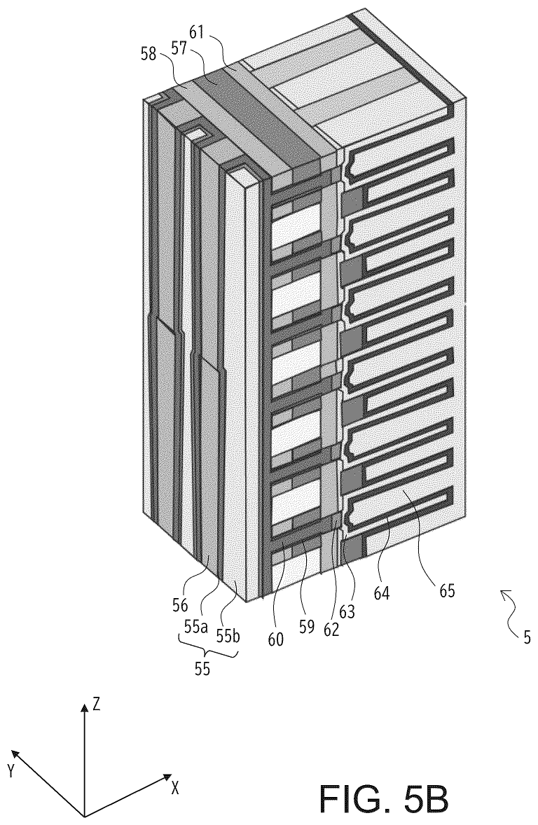

FIG. 5A is a cross-sectional view of the memory chip 5 having the channel formed of the oxide semiconductor layer. As illustrated in FIG. 5A, a memory cell array in the memory chip 5 includes a conductor 21, a conductive layer 22, an electrical conductor 23, an insulator 24, a conductive layer 31, a conductive oxide layer 32, an oxide semiconductor layer 41, a conductive layer 42, an insulating film 43, a conductive oxide layer 51, a conductive layer 52, and a conductive layer 71. Note that FIG. 2 illustrates the oxide semiconductor layer 41, the conductive layer 42, the insulating film 43, and the conductive layer 71 for convenience, and illustration of other components is omitted for convenience.

As illustrated in FIG. 5A, a memory transistor MTR and a memory capacitor MCP are provided above an insulating layer 11 on a semiconductor substrate 10. Peripheral circuits such as a row decoder, a sense amplifier, and a power supply circuit are formed on the semiconductor substrate 10.

The conductor 21, the conductive layer 22, the electrical conductor 23, and the insulator 24 form the memory capacitor MCP. Here, the conductor 21 is connected to a power supply line VPL. The conductor 21 can be disposed as an electrode common to the memory cell array. The conductive layer 22 is electrically common to the conductor 21, and forms one electrode of the memory capacitor. The electrical conductor 23 forms the other electrode of the memory capacitor and is connected to a conductor 30 of each of the memory transistors MTR. The memory capacitor MCP is a three-dimensional capacitor such as a so-called pillar type capacitor or a cylinder type capacitor.

The conductor 21 is provided above the semiconductor substrate 10 with the insulating layer 11 interposed therebetween. The conductive layer 22 is provided on a part of the conductor 21. The conductor 21 and the conductive layer 22 form a second electrode of the memory capacitor MCP. The conductor 21 extends so as to overlap the plurality of electrical conductors 23 when viewed in the Z direction. The conductor 21 is also referred to as a plate electrode. The electrical conductor 23 is provided above the conductor 21 with the insulator 24 interposed therebetween, extends in the Z direction, and forms a first electrode of the memory capacitor MCP. The insulator 24 is provided between the conductor 21 and the conductive layer 22, and the electrical conductor 23, and forms a dielectric of the memory capacitor MCP.

The conductor 21 and the conductive layer 22 contain, for example, a material such as tungsten (W) or titanium nitride (TiN). The electrical conductor 23 contains, for example, a material such as tungsten (W), titanium nitride (TiN), or amorphous silicon. The insulator 24 contains, for example, a material such as hafnium oxide (HfOx), zirconium oxide (ZrOx), or aluminum oxide (AlOx).

The conductive layer 31 is provided on the electrical conductor 23 and is electrically connected to the electrical conductor 23. The conductive layer 31 contains, for example, copper (Cu). Note that the conductive layer 31 is not necessarily formed.

The conductive oxide layer 32 is provided on the conductive layer 31. The conductive oxide layer 32 contains, for example, a metal oxide such as indium (In)-tin (Sn)-oxide (ITO).

The conductive layer 31 and the conductive oxide layer 32 form the conductor 30. The plurality of conductors 30 are provided for the plurality of electrical conductors 23. An insulating layer 33 is formed between the plurality of conductors 30. The insulating layer 33 contains, for example, silicon (Si) and oxygen (O) or nitrogen (N).

The oxide semiconductor layer 41, the conductive layer 42, and the insulating film 43 form the memory transistor MTR. The memory transistor MTR is, for example, an N-channel field effect transistor. The memory transistor MTR is provided above the memory capacitor MCP. The plurality of memory transistors MTR are provided corresponding to a plurality of the memory capacitors MCP. An insulating layer 44 and an insulating layer 45 are formed between the plurality of memory transistors MTR. The insulating layer 44 and the insulating layer 45 contain, for example, silicon (Si) and oxygen (O) or nitrogen (N).

The oxide semiconductor layer 41 is, for example, a columnar body extending in the Z direction. The oxide semiconductor layer 41 penetrates the conductive layer 42 in the Z direction. The oxide semiconductor layer 41 forms a channel of the memory transistor MTR. The oxide semiconductor layer 41 contains, for example, indium (In). The oxide semiconductor layer 41 contains, for example, indium oxide and gallium oxide, indium oxide and zinc oxide, or indium oxide and tin oxide. As an example, the oxide semiconductor layer 41 contains an oxide containing indium, gallium, and zinc (indium-gallium-zinc-oxide), so-called IGZO (InGaZnO). The oxide semiconductor layer 41 may have an amorphous structure or a crystal structure by heat treatment.

One end of the oxide semiconductor layer 41 in the Z direction is connected to the conductive layer 31 via the conductive oxide layer 32, and functions as the other of a source and a drain of the memory transistor MTR. The conductive oxide layer 32 is provided between the electrical conductor 23 of the memory capacitor MCP and the oxide semiconductor layer 41 of the memory transistor MTR, and functions as the other of a source electrode and a drain electrode of the memory transistor MTR. Since the conductive oxide layer 32 contains a metal oxide similarly to the oxide semiconductor layer 41 of the memory transistor MTR, the connection resistance between the memory transistor MTR and the memory capacitor MCP can be reduced.

The conductive layer 42 includes a portion facing the oxide semiconductor layer 41 with the insulating film 43 interposed therebetween in an XY plane. The conductive layer 42 surrounds the oxide semiconductor layer 41 and the insulating film 43 in the XY plane. The conductive layer 42 forms a gate electrode of the memory transistor MTR and forms a word line WL as a wiring. The conductive layer 42 contains, for example, a metal, a metal compound, or a semiconductor. The conductive layer 42 contains, for example, at least one material selected from the group consisting of tungsten (W), titanium (Ti), titanium nitride (TiN), molybdenum (Mo), cobalt (Co), and ruthenium (Ru).

The insulating film 43 is provided between the oxide semiconductor layer 41 and the conductive layer 42 in the XY plane. The insulating film 43 forms a gate insulating film of the memory transistor MTR. The insulating film 43 contains, for example, silicon (Si) and oxygen (O) or nitrogen (N). The insulating film 43 may be a stacked film of a plurality of insulating films.

The memory transistor MTR has a so-called surrounding gate transistor (SGT) structure in which a gate electrode is disposed to surround a channel. The SGT can reduce the area of the semiconductor apparatus 1.

A field effect transistor having a channel layer containing an oxide semiconductor has a lower off-leakage current than a field effect transistor provided on the semiconductor substrate 10. Therefore, for example, since data held in the memory cell MC can be held for a long time, the number of refresh operations can be reduced. In addition, since the field effect transistor having the channel layer containing the oxide semiconductor can be formed by a low-temperature process, it is possible to suppress application of thermal stress to the memory capacitor MCP.

The conductive oxide layer 51 is provided on the oxide semiconductor layer 41. The conductive oxide layer 51 contains, for example, a metal oxide such as indium-tin-oxide (ITO).

The conductive layer 52 is provided on the conductive oxide layer 51 and is electrically connected to the conductive oxide layer 51. The conductive layer 52 contains, for example, copper (Cu).

The conductive oxide layer 51 and the conductive layer 52 form a conductor 50. The conductive layer 52 is a conductive layer for electrically connecting the memory transistor MTR and the bit line BL, and is a main portion of the bit line BL. The conductive oxide layer 51 is a layer for ensuring good electrical connection between the oxide semiconductor layer 41 and the conductive layer 52, and is formed of an electrode material containing an oxide. The conductive layer 52 is electrically connected to and integrated with the conductive oxide layer 51 to form the conductor 50. Usually, an adhesion layer is provided between the conductive oxide layer 51 and the conductive layer 52, but is not illustrated in FIG. 5A. The conductor 50 is electrically connected to the sense amplifier via the bit line BL. The conductor 50 functions as, for example, a conductive pad for connecting the memory transistor MTR and the bit line BL. The conductor 50 is also called a landing pad (LP). A plurality of the conductors 50 are provided corresponding to the plurality of memory transistors MTR. An insulating layer 53 is formed between the plurality of conductors 50. The insulating layer 53 contains, for example, silicon (Si) and oxygen (O) or nitrogen (N).

The other end of the oxide semiconductor layer 41 in the Z direction is connected to the conductive layer 52 via the conductive oxide layer 51, and functions as one of the source and the drain of the memory transistor MTR. The conductive oxide layer 51 functions as one of the source electrode and the drain electrode of the memory transistor MTR. Since the conductive oxide layer 51 contains a metal oxide similarly to the oxide semiconductor layer 41 of the memory transistor MTR, the connection resistance between the memory transistor MTR and the bit line BL can be reduced.

The conductive layer 71 is provided on the conductive layer 52 and connected to the conductor 50. The conductive layer 71 forms the bit line BL as a wiring. An insulating layer 72 is formed between a plurality of the conductive layers 71. The insulating layer 72 contains, for example, silicon and oxygen or nitrogen.

The insulating film 43 to be the gate insulating film of the memory transistor MTR is formed using an oxide film such as a silicon oxide film, but it is preferable to form a nitride film such as a silicon nitride film between the silicon oxide film and the word line (gate electrode) in order to suppress diffusion of a metal element such as tungsten from the word line (gate electrode) to the silicon oxide film.

Although the memory chip 5 in FIG. 5A illustrates an example in which the plurality of memory transistors MTR each having the channel extending in a normal direction of the semiconductor substrate 10 and the plurality of memory capacitors MCP are disposed in a substrate surface direction, the semiconductor apparatus 1 according to the present embodiment may include the memory chip 5 in which the plurality of memory transistors MTR and the plurality of memory capacitors MCP are disposed in a three-dimensional direction.

FIG. 5B is a perspective view illustrating an example of the memory chip 5 having a three-dimensional structure. The memory chip 5 in FIG. 5B includes a plurality of first conductive layers 55 extending in the Z direction in the drawing. These first conductive layers 55 are used as, for example, bit lines. The first conductive layer 55 is, for example, a stacked film of an ITO film 55a and a TiN film 55b. These first conductive layers 55 are disposed to be spaced apart from each other in the Y direction with an insulating layer 56 made of, for example, SiO interposed therebetween.

A plurality of gate wirings 57 extending in the Y direction orthogonal to the plurality of first conductive layers 55 are provided. These gate wirings 57 are used as, for example, word lines. An insulating layer 58 made of, for example, SiN is disposed between the plurality of first conductive layers 55 and the plurality of gate wirings 57. A gate insulating film 59 and an oxide semiconductor layer 60 in which a channel is formed are stacked between two gate wirings 57 adjacent in the Z direction. The oxide semiconductor layer 60 is, for example, an oxide containing indium, gallium, and zinc (indium-gallium-zinc-oxide), so-called IGZO (InGaZnO). The gate wiring 57, the gate insulating film 59, and the oxide semiconductor layer 60 constitute the memory transistor MTR.

The plurality of gate wirings 57 are in contact with an insulating layer 61 made of, for example, SiN. A plurality of second conductive layers 62 made of, for example, indium (In)-tin (Sn)-oxide (ITO) are disposed spaced apart from each other along the Z direction on a surface of the insulating layer 61 opposite to a contact surface with the gate wiring 57. These second conductive layers 62 are used as channel electrodes. A first capacitor electrode 63 is disposed in the Z direction and the X direction so as to be in contact with the second conductive layer 62. The first capacitor electrode 63 is formed of, for example, TiN. The first capacitor electrode 63 is disposed to face a second capacitor electrode 65 made of, for example, TiN via a HK film 64. The first capacitor electrode 63, the HK film 64, and the second capacitor electrode 65 constitute the memory capacitor MCP.

As described above, the memory chip 5 included in the semiconductor apparatus 1 according to the present embodiment may have a two-dimensional structure as illustrated in FIG. 5A or a three-dimensional structure as illustrated in FIG. 5B. In addition, an arrangement direction of each of the memory transistors MTR and each of the memory capacitor MCP is not limited.

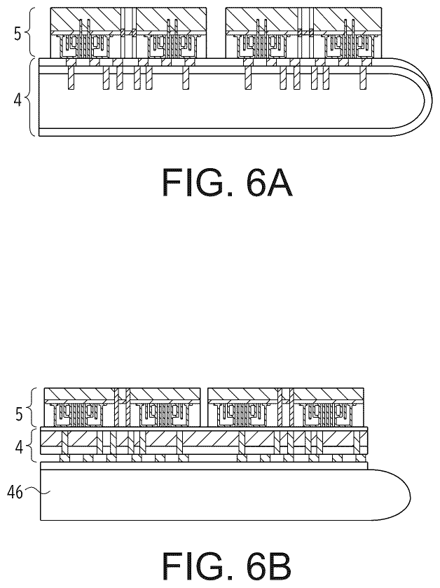

FIG. 6A is a cross-sectional view illustrating a bonding mode between the logic chip 4 and the memory chip 5 at the lowermost stage in the semiconductor apparatus 1 according to the present embodiment, and FIG. 6B is a cross-sectional view illustrating a bonding mode between a logic chip 4 and the memory chip 5 at the lowermost stage in a semiconductor apparatus 1 according to the comparative example.

Each of the memory chips 5 included in the semiconductor apparatus 1 according to the present embodiment has the channel formed of the oxide semiconductor layer, whereas each of the memory chips 5 included in the semiconductor apparatus 1 according to the comparative example has the channel formed of the silicon layer.

In the semiconductor apparatus 1 according to the present embodiment, as illustrated in FIG. 6A, the logic chip 4 and the memory chip 5 are bonded in a state where the logic chip 4 is face up and the memory chip 5 is face down. As illustrated in FIG. 1, the plurality of memory chips 5 are stacked all in a face-down manner on the memory chip 5 at the lowermost stage in FIG. 6A. The logic chip 4 and the memory chip 5 at the lowermost stage are bonded to each other by HB, which requires high temperature heat treatment. Similarly, the stacked memory chips 5 are also bonded to each other by HB.

In the semiconductor apparatus 1 according to the comparative example, as illustrated in FIG. 6B, the logic chip 4 and the memory chip 5 are bonded in a state where both the logic chip 4 and the memory chip 5 are face down. The pads of the logic chip 4 and the pads of the memory chip 5 are connected via bumps. Since the semiconductor apparatus 1 according to the comparative example has the channel formed of the silicon layer, it is not possible to adopt HB, which requires heat treatment at a high temperature.

In the comparative example, since the logic chip 4 is face down, a support substrate 46 is required below the logic chip 4. As the support substrate 46, a wafer or a glass substrate is used. An adhesive used for bonding the logic chip 4 and the support substrate 46 is an organic material, cannot withstand a high temperature of 300° C. or higher, and may cause peeling-off.

As described above, in the semiconductor apparatus 1 according to the comparative example, since each of the memory chips 5 has the channel formed of the silicon layer, the heat treatment at a high temperature exceeding 260° C. cannot be performed, and in addition, there is a temperature restriction that the adhesive used for bonding the logic chip 4 and the support substrate 46 cannot withstand a high temperature of 300° C. or more.

On the other hand, in the semiconductor apparatus 1 according to the present embodiment, since each of the memory chips 5 has the channel formed of the oxide semiconductor layer, there is no restriction on the heat treatment temperature at the time of bonding the memory chips 5 to each other. In addition, in the semiconductor apparatus 1 according to the present embodiment, since the logic chip 4 is face up, a support substrate for supporting the logic chip 4 is unnecessary.

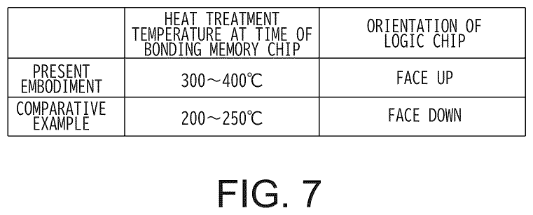

FIG. 7 is a table for comparing the heat treatment temperature at the time of bonding the memory chips 5 to each other and the orientation of the logic chip 4 disposed below the memory chip 5 in the semiconductor apparatus 1 according to the present embodiment and the semiconductor apparatus 1 according to the comparative example.

As illustrated in FIG. 7, the heat treatment temperature at the time of bonding the memory chips 5 to each other in the present embodiment is 300 to 400° C., whereas the heat treatment temperature in the comparative example is 200 to 250° C. In addition, the logic chip 4 in the present embodiment is disposed in a face-up manner, whereas the logic chip 4 in the comparative example is disposed in a face-down manner.

Hereinafter, two representative methods for manufacturing the semiconductor apparatus 1 according to the present embodiment will be described in order. Hereinafter, these two manufacturing methods are referred to as a first process flow and a second process flow.

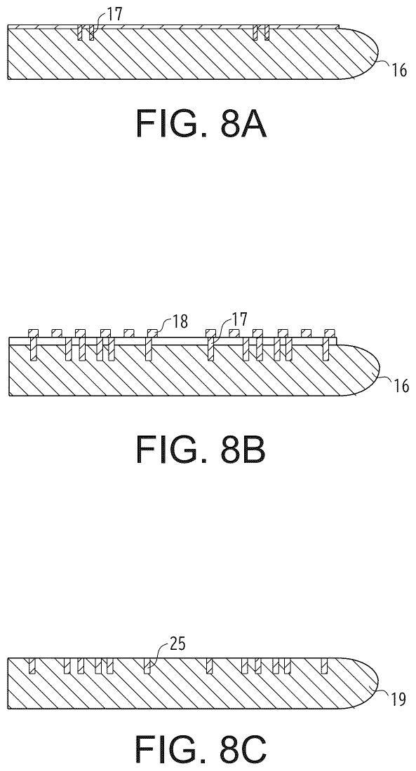

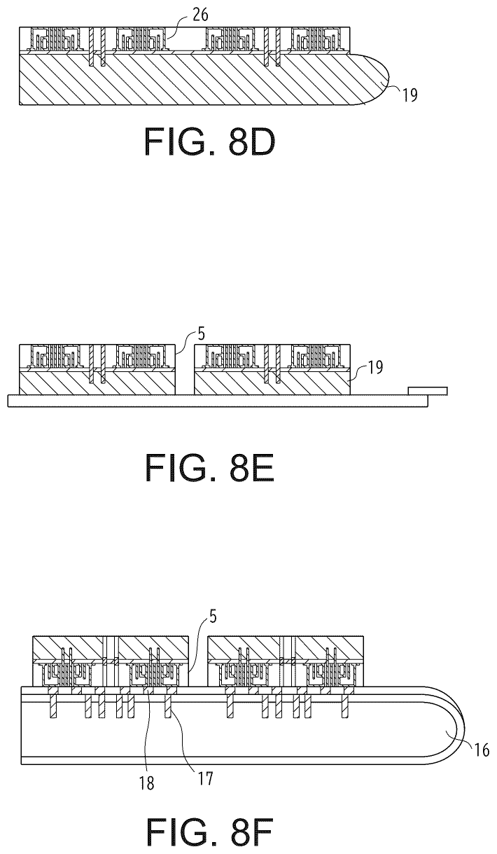

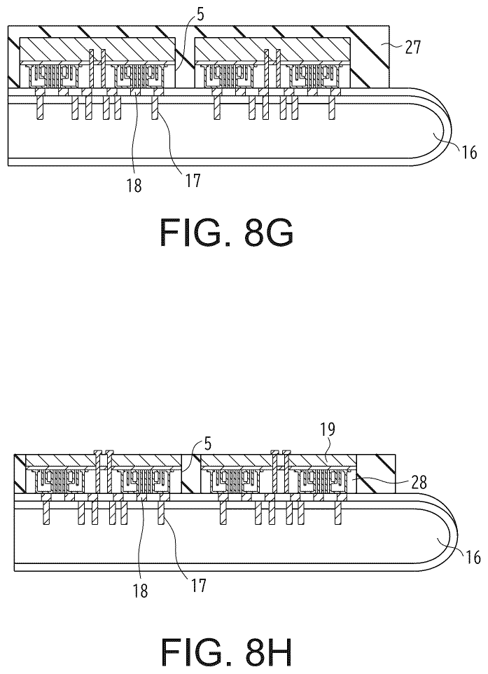

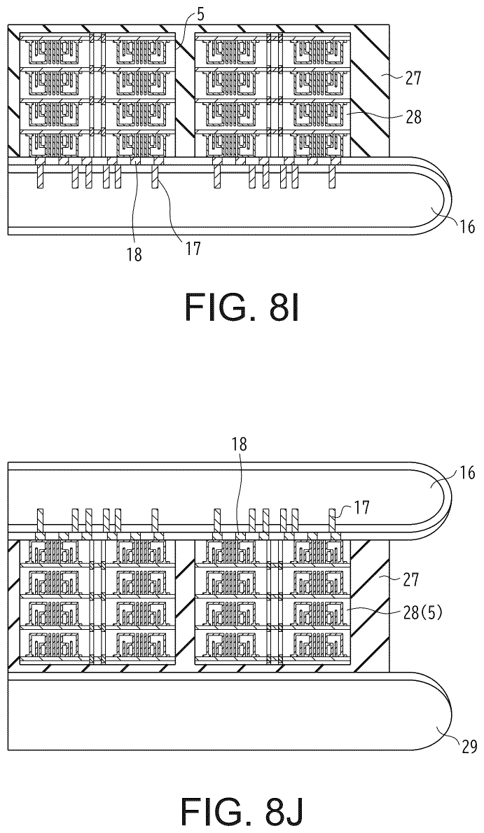

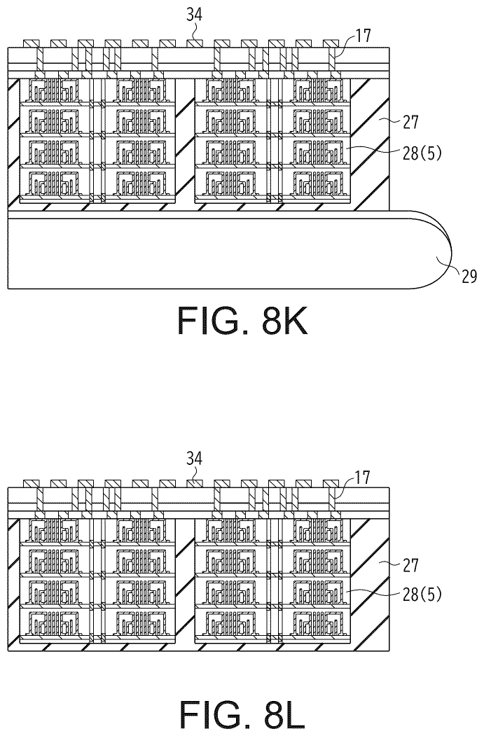

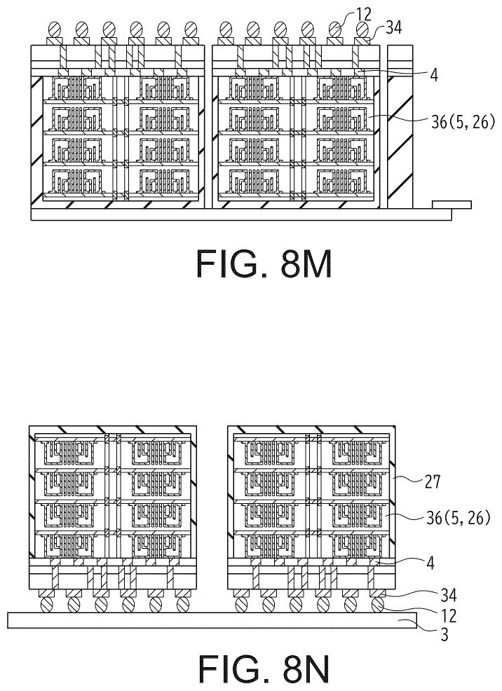

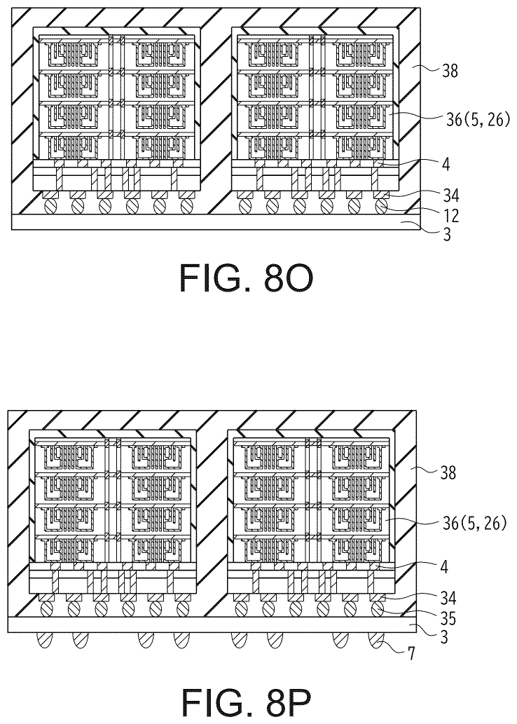

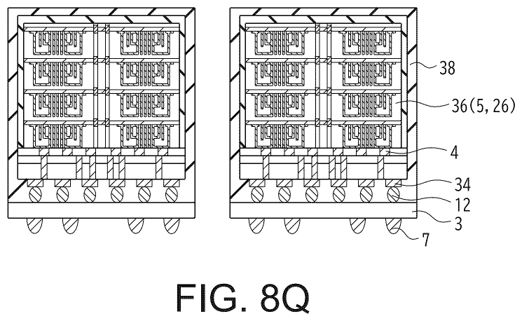

FIGS. 8A to 8Q are process diagrams of the first process flow. First, as illustrated in FIG. 8A, a plurality of trenches are formed on an upper surface of a logic wafer (second substrate) 16 for forming the logic chip 4, and these trenches are filled with a conductive member such as copper (Cu) or tungsten (W) to form a plurality of TSVs (second vias) 17.

Next, as illustrated in FIG. 8B, a logic circuit 18 is formed on the upper surface of the logic wafer 16. Thus, the processing of the logic wafer 16 ends.

The processing of a memory wafer 19 is performed in parallel with or before or after the processing of the logic wafer 16. First, as illustrated in FIG. 8C, a plurality of trenches are formed on an upper surface of the memory wafer 19, and these trenches are filled with a conductive member to form a plurality of TSVs (first vias) 25.

Next, as illustrated in FIG. 8D, a plurality of memory devices 26 are formed on the upper surface of the memory wafer (first substrate) 19. Here, each of the memory devices 26 refers to a plurality of memory cells mounted on one memory chip 5.

Next, as illustrated in FIG. 8E, the memory wafer 19 is thinned by chemical mechanical polishing (CMP) or the like, and the memory devices 26 are singulated together with the thinned memory wafer 19 to form a plurality of memory chips 5. The memory chip 5 includes the singulated memory wafer 19 and memory device 26.

Thus, the processing of the memory wafer 19 ends. As described above, the processing of the logic wafer 16 in FIGS. 8A and 8B and the processing of the memory wafer 19 in FIGS. 8C to 8E are performed in parallel with or before and after each other.

Next, as illustrated in FIG. 8F, in a state where the logic wafer 16 formed with the logic circuit 18 and the TSV 17 is face up and the plurality of singulated memory chips 5 are face down, a pad 15 on the logic wafer 16 and the pad 13 of each of the memory chips 5 are directly bonded, and heat treatment is performed at 300 to 400° C. As described above, the pad 15 on the logic wafer 16 and the pad 13 of each of the memory chips 5 are bonded by HB.

Next, as illustrated in FIG. 8G, the periphery of the plurality of memory chips 5 is covered with an insulating layer 27 such as SiO2.

Next, as illustrated in FIG. 8H, the insulating layer 27 and the memory wafer 19 are thinned by CMP or the like until the TSV 25 of the singulated memory wafer 19 is exposed. As a result, a memory layer 28 for one layer is formed.

Next, as illustrated in FIG. 8I, a process of bonding the plurality of singulated memory chips 5 in a face-down manner on the memory layer 28 at the lowermost stage is repeated to stack a plurality of the memory layers 28 on the logic wafer 16. As a result, for example, the memory layers 28 for 16 layers are stacked. The periphery of the plurality of stacked memory layers 28 is covered with the insulating layer 27 such as SiO2.

Next, as illustrated in FIG. 8J, the logic wafer 16 is pasted in an inverted (face-down) state to a support substrate (third substrate) 29. For example, an adhesive is used for pasting the logic wafer 16 and the support substrate 29.

Next, as illustrated in FIG. 8K, the logic wafer 16 is thinned by CMP or the like until the TSV 17 is exposed, and a pad 34 is formed on a surface of the logic wafer 16 opposite to a bonding surface with the memory chip 5.

Next, as illustrated in FIG. 8L, the support substrate 29 is peeled

off.

Next, as illustrated in FIG. 8M, the solder ball 12 is attached to the pad 34 of the logic wafer 16, and the plurality of memory chips 5 including the logic wafer 16 are singulated. As a result, a plurality of stacked chips 36 are formed. Each of the stacked chips 36 includes the plurality of memory chips 5 stacked on the logic chip 4.

Next, as illustrated in FIG. 8N, the logic chip 4 is inverted (face up), and the solder ball 12 on the lower surface side of the logic chip 4 is bonded to the interposer 3 or a pad 37 of the module substrate 2.

Next, as illustrated in FIG. 8O, a molding process of covering, with a resin member 38, the periphery of the plurality of stacked chips 36 on the interposer 3 or the module substrate 2 is performed.

Next, as illustrated in FIG. 8P, the bump 7 or a solder ball is attached to each of pads 39 on the lower surface side of the interposer 3 or the module substrate 2.

Next, as illustrated in FIG. 8Q, each of the stacked chips 36 is singulated.

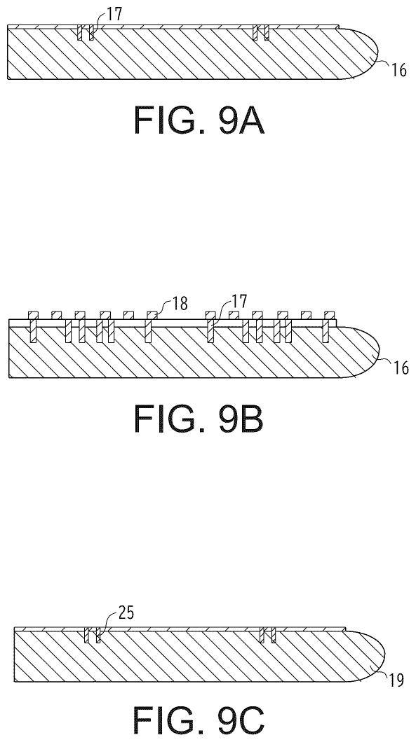

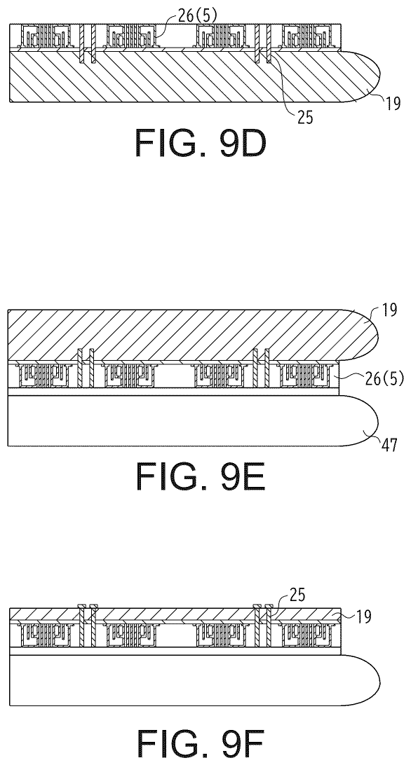

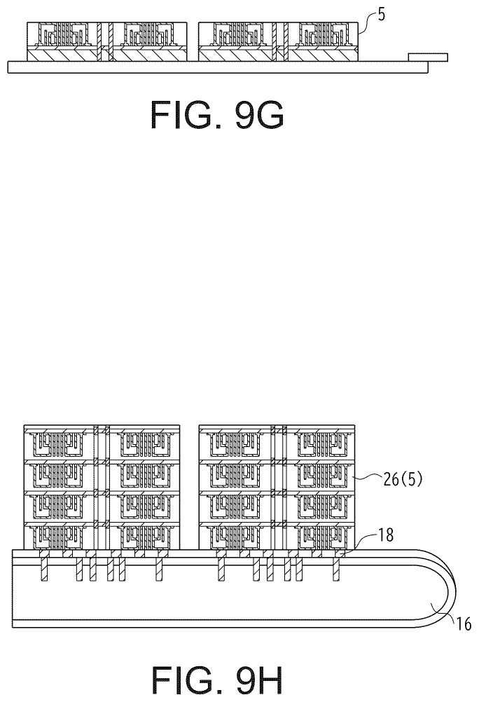

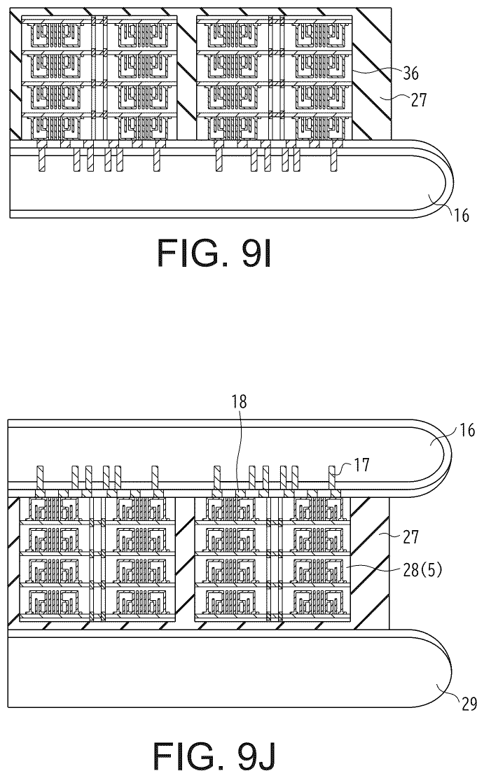

FIGS. 9A to 9J are process diagrams of the second process flow. Hereinafter, differences from the first process flow will be mainly described. The processing of the logic wafer 16 illustrated in FIGS. 9A and 9B is the same as that in FIGS. 8A and 8B.

The process of forming the TSV (first via) 25 and the memory device 26 on the memory wafer (first substrate) 19 in FIGS. 9C and 9D is the same as that in FIGS. 8C and 8D.

After the process in FIG. 9D is completed, the memory wafer 19 is inverted (face down) and pasted to a support substrate (second substrate) 47 as illustrated in FIG. 9E. For example, an adhesive is used for pasting the memory wafer 19 and the support substrate 47.

Next, as illustrated in FIG. 9F, the memory wafer 19 is thinned until the TSV 25 is exposed, and a pad is formed on the surface of the memory wafer 19 opposite to the bonding surface with the memory device 26.

Next, as illustrated in FIG. 9G, the support substrate 47 is peeled off, and the plurality of memory devices 26 including the memory wafer 19 are singulated to form the plurality of memory chips 5.

Next, as illustrated in FIG. 9H, the logic wafer (third substrate) 16 is face up, and the pads of the plurality of memory chips 5 that are face down are bonded to the pads of the logic circuit 18. Next, a process of bonding the pads of the plurality of memory chips 5 that are face down to the pads of the plurality of memory chips 5 that are face down is repeated a plurality of times, and then heat treatment is performed to stack the plurality of memory layers 28 on the logic wafer 16 that is face up. Since the pads are bonded to each other by HB, heat treatment is performed at 300 to 400° C.

Next, as illustrated in FIG. 9I, the periphery of the plurality of stacked chips 36 on the logic wafer 16 is covered with the insulating layer 27 such as SiO2.

Next, as illustrated in FIG. 9J, the logic chip 4 is inverted (face down) and pasted to the support substrate 29. Thereafter, processes similar to those in FIGS. 8K to 8P are performed.

In the first process flow, the heat treatment is performed every time the memory layer 28 is newly stacked, whereas in the second process flow, the heat treatment is performed after all the memory layers 28 are stacked, so that the number of times of heat treatment can be reduced and the manufacturing process can be simplified as compared with the first process flow. In addition, by reducing the number of times of heat treatment, damage to the semiconductor apparatus 1 can be reduced.

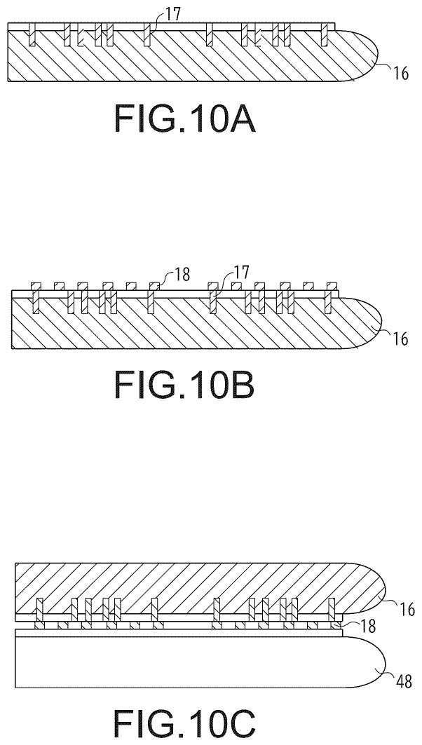

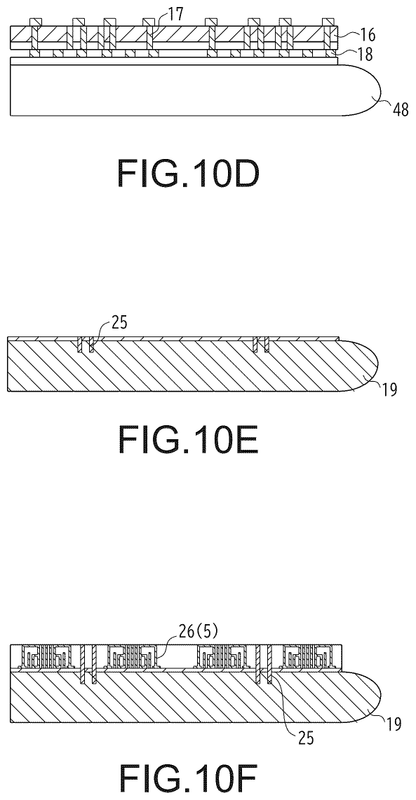

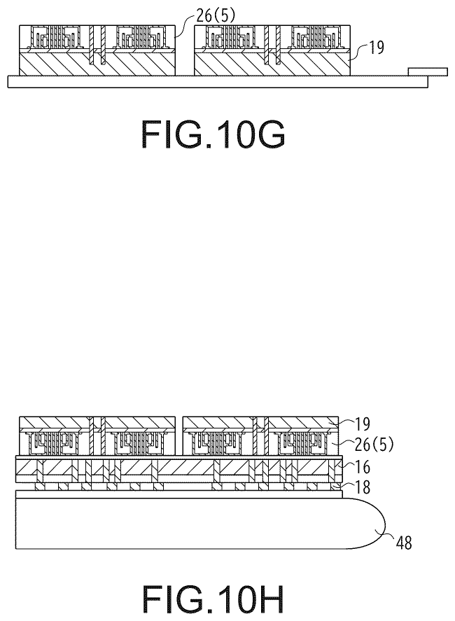

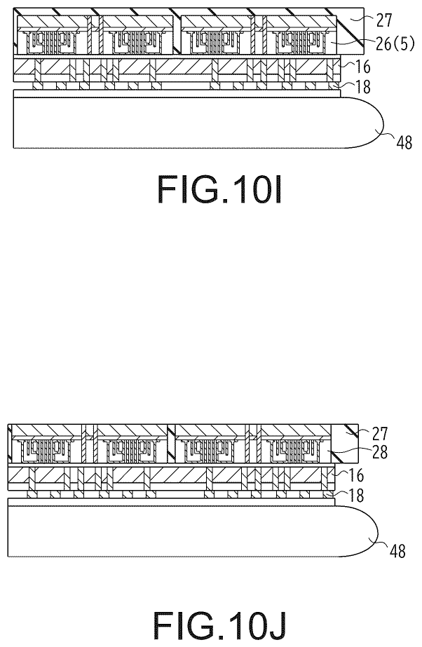

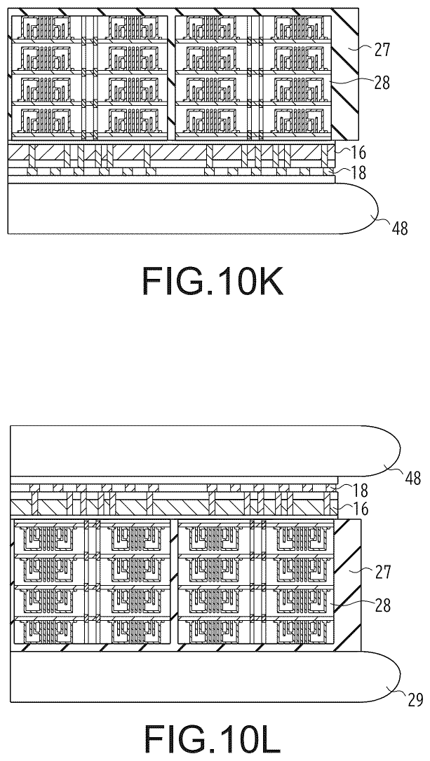

FIGS. 10A to 10L are process diagrams illustrating a method for manufacturing the semiconductor apparatus 1 according to the comparative example. The process in FIGS. 10A and 10B is the same as that in FIGS. 8A and 8B. When the process in FIG. 10B is completed, the logic wafer 16 is inverted (face down) and pasted to a support substrate 48 as illustrated in FIG. 10C.

Next, as illustrated in FIG. 10D, the logic wafer 16 is thinned until the TSV 17 is exposed. Through the above processes in FIGS. 10A to 10D, the processing of the logic wafer 16 ends.

In parallel with or before or after the processing of the logic wafer 16, a plurality of trenches are formed on the memory wafer 19, and each of the trenches is filled with a conductive member to form the plurality of TSVs 25 as illustrated in FIG. 10E.

Next, as illustrated in FIG. 10F, the plurality of memory devices 26 are formed on the memory wafer 19.

Next, as illustrated in FIG. 10G, the memory wafer 19 is thinned until the TSV 25 is exposed, and the plurality of memory devices 26 including the memory wafer 19 are singulated to form the plurality of memory chips 5.

Next, as illustrated in FIG. 10H, the plurality of singulated memory chips 5 are bonded in a face-down manner onto the logic wafer 16 via bumps. Since the memory chip 5 of the comparative example has the channel formed of the silicon layer, heat treatment cannot be performed at high temperature. Therefore, heat treatment is performed at 200 to 250° C. at which the bump melts.

Next, as illustrated in FIG. 10I, the periphery of each of the memory devices 26 is covered with the insulating layer 27 such as SiO2.

Next, as illustrated in FIG. 10J, the insulating layer 27 and the memory chip 5 are thinned until the TSV 25 is exposed, and the memory layer 28 for one layer is formed.

Next, as illustrated in FIG. 10K, the plurality of memory chips 5 are bonded onto the memory layer 28 via bumps, heat treatment is performed, and thereafter, a process of forming the insulating layer 27 and thinning the insulating layer is repeated a plurality of times to form the plurality of memory layers 28 on the logic chip 4.

Next, as illustrated in FIG. 10L, the support substrate 48 is inverted and bonded to another support substrate 29. Next, the support substrate 48 is peeled off, and the same processes as those in FIGS. 8K to 8P are performed.

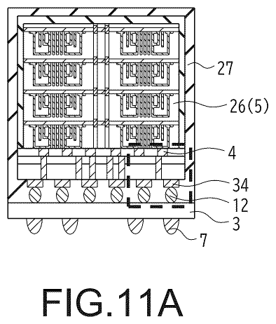

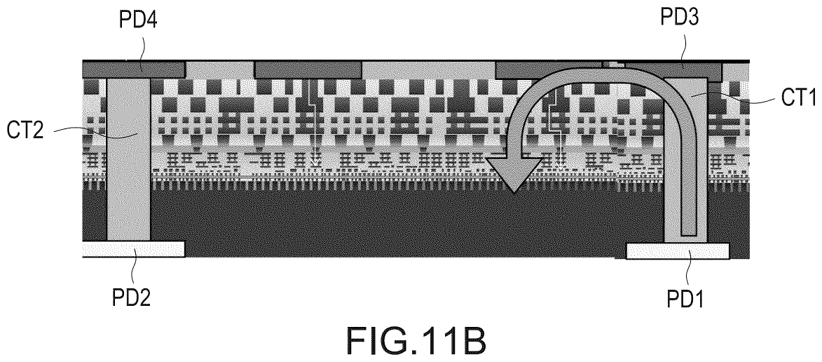

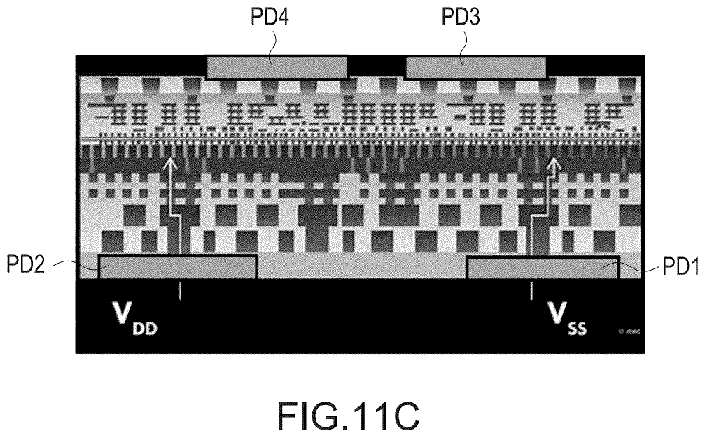

Next, as illustrated in FIG. 11A or FIG. 8Q, each of the stacked chips 36 is singulated.

As described above, in the present embodiment, the logic chip 4 and the memory chip 5 are bonded by, for example, HB in a state where the logic chip 4 is face up and the memory chip 5 is face down. Therefore, power supply to each device in the logic chip 4 can be performed from the lower surface side of the logic chip 4.

FIG. 11A is a cross-sectional view of the semiconductor apparatus 1 according to the present embodiment, and FIGS. 11B and 11C are cross-sectional views of portions of the logic chip 4 indicated by broken lines in FIG. 11A.

As illustrated in FIG. 11A, a first pad PD1 for supplying a power supply voltage and a second pad PD2 for supplying a ground voltage are provided on the lower surface of the logic chip 4. A first contact CT1 and a second contact CT2 penetrating the logic chip 4 are connected to the first pad PD1 and the second pad PD2, respectively. A third pad PD3 connected to the first contact CT1 and a fourth pad PD4 connected to the second contact CT2 are provided on the upper surface of the logic chip 4.

The power supply voltage is supplied from the first pad PD1 to each device in the logic chip 4 via the first contact CT1 and the third pad PD3. In addition, the ground voltage is supplied from the second pad PD2 to each device in the logic chip 4 via the second contact CT2 and the fourth pad PD4.

In addition, each of the third pad PD3 and the fourth pad PD4 is directly bonded to the corresponding pad of the memory device 26, and the power supply voltage and the ground voltage are supplied to the memory device 26 via the third pad PD3 and the fourth pad PD4.

Unlike FIG. 11B, FIG. 11C illustrates an example in which the power supply voltage and the ground voltage are supplied from the first pad PD1 and the second pad PD2 on the back surface side of the logic chip 4 to each device in the logic chip 4 by post-process wiring.

As described above, when the first pad PD1 for the power supply voltage and the second pad PD2 for the ground voltage are provided on the back surface side of the logic chip 4, these voltages may be supplied to the third pad PD3 and the fourth pad PD4 on the upper surface side via the first contact CT1 and the second contact CT2, and the power supply voltage and the ground voltage may be supplied to each device from the upper surface side of the logic chip 4, or the power supply voltage and the ground voltage may be supplied to each device from the first pad PD1 and the second pad PD2 on the back surface side of the logic chip 4 by post-process wiring.

As described above, in the present embodiment, since each of the stacked memory chips 5 has the channel formed of the oxide semiconductor layer, it is possible to adopt HB, which requires high temperature heat treatment for bonding the memory chip 5 and the logic chip 4 and bonding the memory chips 5 to each other, and it is possible to improve the transmission speed without causing the VRT failure of the memory chip 5.

In addition, the logic chip 4 and the memory chip 5 can be bonded by HB in a state where the logic chip 4 is face up and the memory chip 5 is face down. Therefore, it is not necessary for bonding the logic chip 4 and the memory chip 5 to use an adhesive that cannot withstand high heat, and the reliability of bonding of the logic chip 4 and the memory chip 5 is improved.

Furthermore, in the present embodiment, since the supply of the power supply voltage and the ground voltage to each device in the logic chip 4 can be performed from the lower surface side of the logic chip, and the path of the power supply line can be shortened, the voltage drop of the power supply line can be suppressed, and the power consumption can be reduced.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. A semiconductor apparatus comprising:
a logic chip on which a logic circuit is disposed; and
a plurality of memory chips stacked on the logic chip that is face up, wherein
each of the plurality of memory chips has a channel formed of an oxide semiconductor layer.

2. The semiconductor apparatus according to claim 1, wherein
the oxide semiconductor layer is IGZO: InGaZnO containing indium (In), gallium (Ga), and zinc (Zn).

3. The semiconductor apparatus according to claim 1, wherein
in the memory chips stacked on each other, pads are directly bonded to each other.

4. The semiconductor apparatus according to claim 1, wherein
each of the plurality of memory chips stacked is disposed in a face-down manner.

5. The semiconductor apparatus according to claim 4, wherein
in the logic chip that is face up and the memory chip that is face down at a lowermost stage, pads are directly bonded to each other.

6. The semiconductor apparatus according to claim 1, further comprising:
a first pad that supplies a power supply voltage disposed on a lower surface of the logic chip;
a second pad that supplies a ground voltage disposed on the lower surface of the logic chip;
a first contact connected to the first pad and that penetrates the logic chip;
a second contact connected to the second pad and that penetrates the logic chip;
a third pad disposed on an upper surface of the logic chip and connected to the first contact; and
a fourth pad disposed on the upper surface of the logic chip and connected to the second contact, wherein
the power supply voltage is supplied from the third pad and the ground voltage is supplied from the fourth pad to a plurality of devices in the logic chip.

7. The semiconductor apparatus according to claim 1, further comprising:
a first pad that supplies a power supply voltage disposed on a lower surface of the logic chip; and
a second pad that supplies a ground voltage disposed on the lower surface of the logic chip, wherein
the power supply voltage is supplied from the first pad and the ground voltage is supplied from the second pad to a plurality of devices in the logic chip.

8. The semiconductor apparatus according to claim 1, further comprising:
a processor chip; and
an interposer or a module substrate disposed below the logic chip and the processor chip.

9. The semiconductor apparatus according to claim 1, wherein
each of the plurality of memory chips is a high bandwidth memory (HBM) chip.

10. A method for manufacturing a semiconductor apparatus, comprising:
forming a first via in a first substrate;
separately forming, on the first substrate, a plurality of memory devices each having a channel formed of an oxide semiconductor layer;
thinning the first substrate and singulating the plurality of memory devices including the first substrate to form a plurality of memory chips;
directly bonding, in a state where a second substrate formed with a logic circuit and a second via is face up and the plurality of memory chips are face down, pads of the logic circuit and pads of the plurality of memory chips and performing heat treatment to bond a memory layer including the plurality of memory chips to the second substrate; and
disposing the plurality of memory chips that are face down on the memory layer, and repeating a process of directly bonding pads of the memory layer and pads of the plurality of memory chips and performing heat treatment to stack a plurality of the memory layers on the second substrate.

11. The method for manufacturing a semiconductor apparatus according to claim 10, wherein
the step of bonding the memory layer to the second substrate comprises:
directly bonding the pads of the logic circuit that is face up and the pads of the plurality of memory chips that are face down and performing heat treatment;
covering, with an insulating layer, a periphery of the plurality of memory chips; and
thinning the insulating layer and the first substrate included in each of the plurality of memory chips to form the memory layer for one layer.

12. The method for manufacturing a semiconductor apparatus according to claim 10, further comprising:
covering, with an insulating layer, a periphery of the plurality of memory chips stacked;
pasting the second substrate in a face-down manner to a third substrate;
thinning the second substrate until the second via is exposed and forming, on an upper surface of the second substrate, a pad electrically connected to the second via;
peeling off the third substrate;
singulating the plurality of memory chips including the second substrate to form a plurality of stacked chips; and
bonding the plurality of stacked chips in a face-up manner to an interposer or a module substrate.

13. The method for manufacturing a semiconductor apparatus according to claim 10, wherein
the oxide semiconductor layer is IGZO: InGaZnO containing indium (In), gallium (Ga), and zinc (Zn).

14. The method for manufacturing a semiconductor apparatus according to claim 10, wherein
each of the plurality of memory chips is a high bandwidth memory (HBM) chip.

15. A method for manufacturing a semiconductor apparatus, comprising:
forming a first via in a first substrate;
separately forming, on the first substrate, a plurality of memory devices each having a channel formed of an oxide semiconductor layer;
pasting the first substrate in a face-down manner to a second substrate;
thinning the first substrate;
peeling off the second substrate and singulating the plurality of memory devices including the first substrate to form a plurality of memory chips;
making a third substrate formed with a logic circuit and a second via face up and bonding pads of the plurality of memory chips that are face down to pads of the third substrate; and
repeating a process of bonding, to pads of the plurality of memory chips, pads of the plurality of memory chips that are new and face down and then performing heat treatment to form a plurality of memory layers on the third substrate.

16. The method for manufacturing a semiconductor apparatus according to claim 15, wherein
when the new plurality of memory chips are disposed on the plurality of memory chips, heat treatment is not performed, and after arrangement of the plurality of memory chips for a plurality of layers is completed, heat treatment is performed to form the plurality of memory layers.

17. The method for manufacturing a semiconductor apparatus according to claim 16, further comprising:
covering, with an insulating layer, a periphery of the plurality of memory layers stacked;
pasting the third substrate in a face-down manner to a fourth substrate;
thinning the third substrate until the second via is exposed and forming, on an upper surface of the third substrate, a pad electrically connected to the second via;
peeling off the fourth substrate;
singulating the plurality of memory layers including the third substrate to form a plurality of stacked chips; and
bonding the plurality of stacked chips in a face-up manner to an interposer or a module substrate.

18. The method for manufacturing a semiconductor apparatus according to claim 16, wherein
the oxide semiconductor layer is IGZO: InGaZnO containing indium (In), gallium (Ga), and zinc (Zn).

19. The method for manufacturing a semiconductor apparatus according to claim 16, wherein
each of the plurality of memory chips is a high bandwidth memory (HBM) chip.
